(19) United States
(12) Patent Application Publication
(10) Pub. No.: US 2010/0146781 A1
(43) Pub. Date: Jun. 17, 2010

(54) METHOD IN MANUFACTURING OF CIRCUIT BOARDS

(75) Inventors: Antti Salminen, Lappeenranta (FI); Rauno Holappa, Oulunsalo (FI)

Correspondence Address: VOLPE AND KOENIG, P.C., UNITED PLAZA, SUITE 1600, 30 SOUTH 17TH STREET, PHILADELPHIA, PA, 19103, US

(73) Assignee: FINNISH ENVIRONMENT TECHNOLOGY OY, Oulunsalo (FI)

(21) Appl. No.: 12/601,142

(22) PCT Filed: May 29, 2008
(86) PCT No.: PCT/FI08/50312

§ 371 Date: Jan. 21, 2010

(30) Foreign Application Priority Data
Jun. 7, 2007 (FI) 20070453
Nov. 26, 2007 (FI) 20070904

(51) Int. Cl. H05K 3/42; H05K 3/46; H05K 3/02

(52) U.S. Cl. 29/851; 29/846; 29/852

(57) ABSTRACT

Method for connecting the conductive surfaces of circuit boards, especially a circuit board equipped with at least two conductive surfaces separated by an insulator layer and with holes, or for creating conductors on a board in a manner that conducts electricity. In the method, a metal or metal alloy, in a powder form, is fed into and the powder is sintered using a laser in order to create a unified conductive structure.

### FIELD OF THE INVENTION

The present invention relates to a method for use in the manufacture of circuit boards.

### BACKGROUND

Various kinds of circuit board are nowadays very widely used in the most diverse applications, ranging from simple applications to extremely complex, large-scale applications.

Previously, circuit boards were one-sided structures, in that, on one side of an insulating baseboard there was a copper layer used for connections, which was etched in a suitable manner to form conductive and non-conductive areas. The components were soldered onto the most suitable locations on the copper surface.

Nowadays, circuit boards have a copper layer on both sides of an insulating board, because technology is continuously developing in the direction of miniaturization and situating components in the smallest possible space is economical in terms of manufacturing technique. Thus, both sides of the circuit board can be exploited.

Many different materials, with varying mechanical, chemical, and electrical properties, are used as the base material of circuit boards. One generally used material is a board made from glass-fibre and epoxy resin, which is often generally referred to by the name FR.4. The properties of the board are good and also include fire-resistant substances, allowing the fire resistance required in demanding locations to be achieved.

Holes are made in circuit boards, through which an electrical connection is intended to be taken to the other side of the board. In certain circumstances, the ‘foot’ of the component being placed on the circuit board can be attached by soldering to the copper layer on both sides of the board, when a connection is also made between the layers.

Another way is to perform so-called through-coppering, when a copper bridge is formed through the hole, between the copper layers on the various surfaces of the circuit board.

A third way is to insert into the hole a tight-fitting copper sleeve, which, if necessary, can be soldered onto the copper layers.

As already stated, circuits can be made on the surface of a circuit board by etching away the unnecessary parts of the copper layer, i.e. by leaving only that part of the copper layer that is required for the circuit. This method is the result of a long product-development process and is, at present, performed on automated production lines. The copper layer removed by etching is recovered from the acids after etching. Machining can also be performed using a laser, in which case the excess copper is vaporized from the surface. The circuit pattern is thus created in the said manner by removing the unnecessary copper from the surface of the FR4.

Creating a circuit in this manner is, of course, an extremely inefficient method, as in most cases more than 90% of the copper layer, which has been made on the surface of the FR4 using a complex production process, is removed.

### SUMMARY

The present invention is intended to create a method, which the aid of which the said connecting of the two surfaces of a circuit board to each other, as well as the creation of a circuit pattern on the surface of the circuit board, can be performed rapidly, certainly, and economically.

The aforementioned and other advantages and benefits of the present invention are achieved in the manner described as characteristic in the accompanying claims.

### BRIEF DESCRIPTION OF THE DRAWINGS

FIG. 1 shows schematically the progress of the process of the invention, when the conducting layers on the different surfaces of a circuit board are connected according to the invention; and

FIG. 2 shows, for its part, the use of a laser, when it is intended to make a circuit pattern on the surface of a circuit board.

### DETAILED DESCRIPTION OF THE PREFERRED EMBODIMENTS

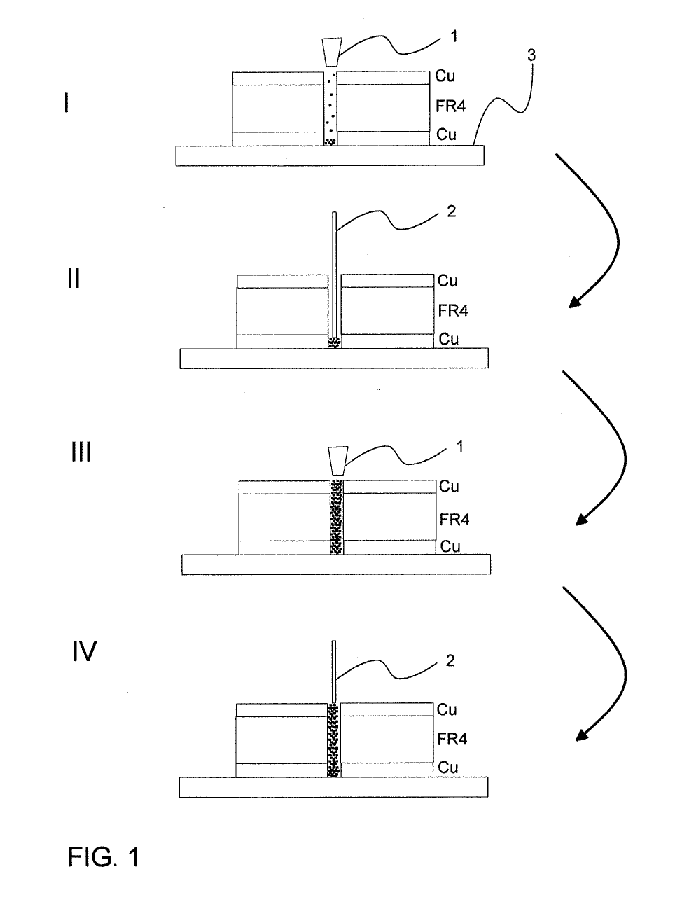

The event according to FIG. 1 is described first.

The invention's basic principle is that, in order to create a quick method, which can be easily integrated in the manufacturing process, a laser is used to connect together the copper layers on the different sides of the card. The laser can be the same laser that is generally used to make holes in the card, but it is obvious that the overall intention is to use a laser with a wavelength suitable for the purpose.

As stated, the holes in the circuit board can be made using a laser that may further comprise a laser unit operating on two different wavelengths, one of which is used for penetrating the copper and the other for penetrating the insulator layer between the copper layers.

According to the invention, particulate copper or a material containing copper is used for forming a contact, and, in fact, for filling a hole. This material is suitably fed into the hole, the fed material is sintered into an essentially solid form, the addition of the particulate material and the sintering of the new batch being repeated as many times as necessary to create the required contact.

FIG. 1 shows that on both sides of the insulator layer FR4 there is a copper layer Cu. The hole is made through all the layers, when the circuit board is placed on a baseboard 3. A powder nozzle 1 is used to bring a batch of powder to the hole. In the next stage, the laser 2 sinters the powder in the hole and these stages are repeated as many times as necessary. In this case, the repetition takes place only once. In this way, an electrical conductor is created between the copper layers Cu.

The method according to the invention is quick and, as stated, can be easily integrated into existing manufacturing systems.

The wavelength of the laser used can be, for example, 532 nm, which is generally used when one and the same laser is used to make holes through both the copper and the insulator layer of a circuit card. Of course, other wavelengths too are available. Under normal conditions, 10 600 nm can be regarded as some sort of a non-restricting upper limit to the wavelength. The power of the laser is selected to achieve sufficiently rapid sintering of the copper powder.

In the known manner, the situation on the circuit board can be such that the hole to be drilled extends through both the insulator layer and both copper layers. It is then obvious that sintering will take place on top of a base, to which the copper to be sintered will not adhere. If the hole extends to the copper layer of the second surface without penetrating it, the aforementioned problem will not arise, instead the addition and sintering of the powder will commence from the bottom of the hole.

Obviously, some suitable device must be used to dose the copper powder into the hole. As such, there is no intention here to consider the operation of the feed device, as easily modifiable devices, developed for other applications, can be found for this purpose. It is important for the device to be sufficiently fast and the dosing of the powder to be sufficiently accurate to ensure a good final result.

Electrical conductivity is of primary importance in the manufacture of circuit boards. Thus in a sintered hole the electrical conductivity should be at least of the same order as in the 30-micrometre-thick copper film that is generally used on the surface of the insulating layer of circuit boards. However, this dimension can vary according to the intended purpose, so that the electrical conductivity of the hole too must be adjusted correspondingly.

Even though copper as a powder, or a powder with a sufficiently large copper content, is the primary sintering substance, the corresponding properties can, of course, be achieved using other metals, or metal alloys. Nowadays, however, the use of lead as a metal is neither desirable, nor even perhaps permitted.

In the best case, the sintered metal or metal alloy would be slightly flexible, because under certain conditions the operation of circuit boards might mean limited thickness variations in the insulator layer.

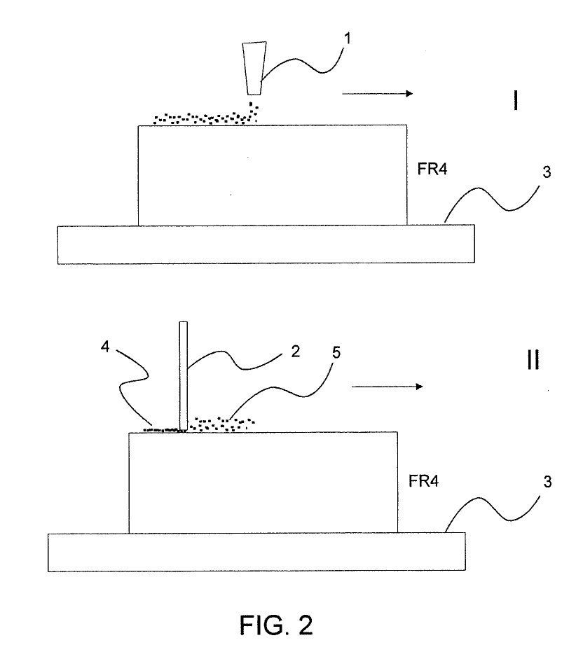

According to FIG. 2 shows schematically a second embodiment of the invention.

According to the second embodiment of the invention, the electrical conductivity too of the surface of the circuit board is produced by sintering copper powder directly onto the insulator, for example, onto the surface of an FR4 board. Sintering is performed by spreading on the surface of the board powdered copper, which is heated by a laser to sintering temperature. The material is kept at this temperature long enough for the powder particles to fuse. The sintering copper slightly melts the surface of the insulator, so that the copper adheres firmly to it.

FIG. 2 shows how the process proceeds from the spreading of the powder to the sintering. Thus a solder of particulate copper, of the desired width and shape, is spread onto the surface of the insulator FR4, from a nozzle I, Stage 1, as in the previous embodiment too. A laser 2 follows the nozzle 1, sintering the spread copper powder onto the surface of the insulator, Stage II. The sintered part is marked with the reference number 4 and the unsintered part, in the direction of which the laser beam travels, with the reference number 5. The progress of the heating process can be monitored by temperature measurement during the process, which can be performed using, for example, a pyrometer.

The powder can be fed using a digitally-controlled nozzle, and can be spread in a even layer over the entire area, for example, using a spatula. The unused powder remaining after the treatment can then be reused. The powder can also be spread in place using a mask, especially when manufacturing larger series. If the feed of the powder takes longer than the heating, the powder can be fed from several nozzles simultaneously while the laser treatment takes place at another location on the product.

The material to be sintered is selected in terms of both particle size and composition to suit the purpose according to the invention. The process can be adjusted in many ways, by selecting the laser to be used and its power, the time and power to be used for sintering, and other parameters, in order to achieve a good result.

The necessary laser device consists of a laser with a suitable wavelength and power, and the beam of which can be controlled with sufficient accuracy. The size of the beam must also be such that the cross-section of the conductor created will be sufficiently large to ensure a sufficient electrical conductivity, and sufficiently narrow for the circuit not to take up more space than the width of the conductor and insulating gap achieved with present technology. In practice, a conductor with a width of less than 100 μm and preferably one as narrow as 25 μm should be achieved. This requires a reasonably good quality of beam, for example, a fibre laser. The various versions of a Nd: Y AG laser and a diode laser can also be suitable for the purpose.

Many variations of the invention are possible, while nevertheless remaining within the defining protection of the accompanying Claims.

1. Method for forming the conductive parts of circuit boards, especially a circuit board equipped with two conductive surfaces, separated by an insulator layer, and with holes, in a manner that conducts electricity, comprising:
providing a metal or metal alloy, in a powder form, that is fed into the holes connecting the surfaces, or on top of the insulator layer of the circuit board, wherein the powder is sintered using a laser in order to create a unified conductive structure, and, if necessary, the addition and sintering of the powder is repeated a sufficient number of times to achieve the a desired electrical conductivity.

2. Method according to claim 1, wherein copper powder is used as the powder.

3. Method according to claim 1, wherein a powder with a copper content is used as the powder.

4. Method according to claim 1, wherein a laser, the wavelength of which is in the range 532-10 600 nm, is used.

5. Method according to claim 1, wherein a conductive metal, or metal alloy, in a particulate form is spread on the insulator surface of the circuit board, and the particulate material is sintered as a desired pattern to adhere to the insulator surface, in order to create a conductive component.

6. Method according to claim 5, wherein the metal/metal alloy in a particulate form is spread on the insulator surface, essentially as a line of the desired width.

7. Method according to claim 5, wherein the metal/metal allow in a particulate form is spread to form a layer over essentially the entire area of the circuit board and is sintered only in the parts in which conductivity is desired, by removing the unsintered materials.
